(19) United States
(12) Patent Application Publication
(10) Pub. No.: US 2008/0186669 A1
(43) Pub. Date: Aug. 7, 2008

(54) Computer case fixing structure

(75) Inventor: Hung-Chieh Chang, Shiji City (TW)

Correspondence Address: TROXELL LAW OFFICE PLLC, SUITE 1404, 5205 LEESBURG PIKE, FALLS CHURCH, VA, 22041, US

(73) Assignee: Clientron Corp.

(21) Appl. No.: 11/701,544

(22) Filed: Feb. 2, 2007

(51) Int. Cl. H05K 7/20

(52) U.S. Cl. 361/687

(57) ABSTRACT

The present invention relates to a computer case fixing structure. The computer case fixing structure is a bracket, which is bended to form a reception chamber. The bracket has a protrudent part at the middle of one side. The protrudent part has a plurality of openings formed thereon so that a computer case can be inserted into the reception chamber of the bracket for being hung and positioned by the use of the openings of the protrudent part.

### FIELD OF THE INVENTION

The present invention relates to a computer case fixing structure, and more particularly to a computer case fixing structure that has a [symbol] -shaped reception chamber for insertion thereinto of a computer case to be applicable to a LCD monitor or the like.

### BACKGROUND OF THE INVENTION

The general desktop computer is generally composed of a monitor and a computer case, wherein a LCD (Liquid Crystal Display) monitor is adopted by most people instead of a conventional CRT (Cathode Ray Tube) monitor. In addition, continuing efforts are made to reduce the size of the computer case for satisfying the requirement of making the computer case lightweight, thin and small.

The conventional computer case is typically mounted beside a computer table or on the ground under the computer table. In addition, various peripheral connectors can be inserted into the backside of the computer case. The conventional computer case occupies more space and the required lengths of the power cords for connecting the peripherals with the computer case must be longer correspondingly. Nowadays, there is disclosed an improved minitype or barebone computer, which has a small size, so the conventional computer case does not satisfy the requirement for use.

Accordingly, according to the motive of the present invention, the present inventor makes diligent studies in providing consumers with a computer case fixing structure for holding a minitype or barebone computer, wherein the computer case fixing structure does not occupy space and is easy to practice.

### SUMMARY OF THE INVENTION

It is a primary object of the present invention to provide a computer case fixing structure, wherein a bracket has a protrudent part to form a reception chamber for positioning a computer case in the bracket to increase the entire practicability.

It is secondary object of the present invention to provide a computer case fixing structure, wherein a bracket has a protrudent part having several openings formed thereon to position the computer case for thereby providing convenience and practicability.

It is tertiary object of the present invention to provide a computer case fixing structure, wherein a bracket has a protrudent part and several heat dissipation holes formed thereon to facilitate the heat dissipation of the computer case inserted into the bracket for thereby increasing entire practicability.

In order to achieve the foregoing objects, the present invention discloses a computer case fixing structure. The computer case fixing structure is a bracket, which is bended to form a reception chamber. The bracket has a protrudent part at the middle of one side. The protrudent part has several openings formed thereon so that a computer case can be inserted into the reception chamber of the bracket for being hung and positioned by the use of the openings of the protrudent part.

The aforementioned objects and advantages of the present invention will be readily clarified in the description of the preferred embodiments and the enclosed drawings of the present invention.

### BRIEF DESCRIPTION OF THE DRAWINGS

FIG. 1 is an elevational view showing a preferred embodiment of the present invention.

FIG. 2 is an elevational view showing another side of the preferred embodiment of the present invention.

FIG. 3 is a schematic view showing the use of the preferred embodiment of the present invention.

FIG. 4 is a schematic elevational exploded view showing the use of the preferred embodiment of the present invention.

### DETAILED DESCRIPTION OF THE PREFERRED EMBODIMENT

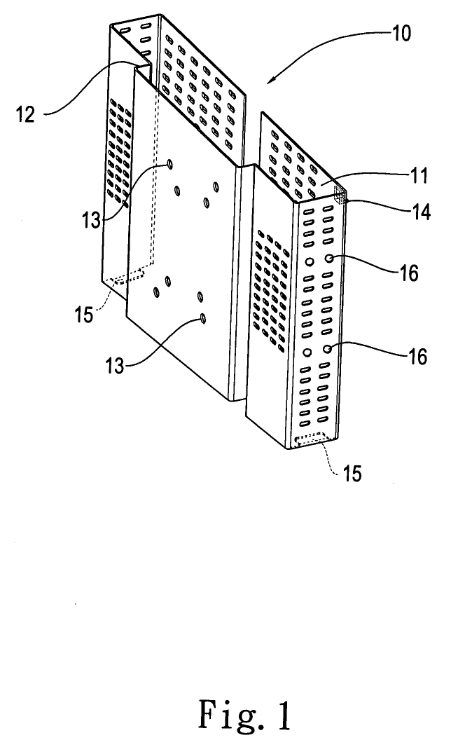

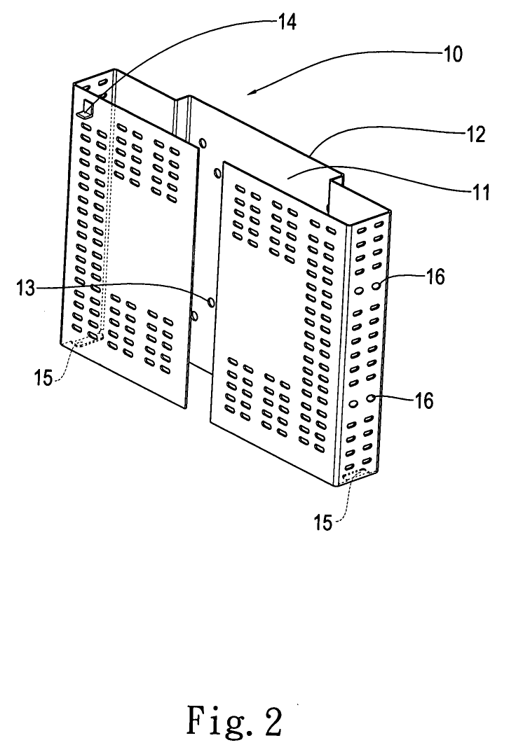

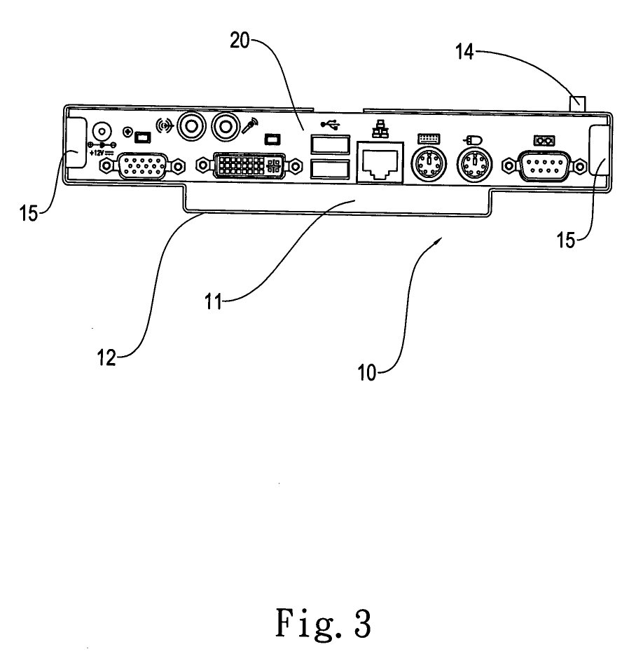

Referring to FIGS. 1 through 3, a computer case fixing structure of the present invention is a bracket 10, which is bended to form a [symbol] -shaped reception chamber 11 for holding a computer case 20, wherein the bracket 10 has a protrudent part 12 formed centrally on one side. For the purpose of positioning the bracket 10, the protrudent part 12 has several openings 13 formed thereon. These openings 13 are in compliance with a VESA (Video Electronics Standards Association) standard, wherein the openings 13 on four corners of the protrudent part 12 are spaced 75 mm×75 mm or 100 mm×100 mm to meet the VESA standard. The other side of the bracket 10 is bended to form two plates so as to facilitate insertion and positioning of the computer case 20 into the expandable reception chamber 10. The bracket 10 has several coupling holes 16 formed on one side. In addition, the bracket 10 further has a hooking part 14 for hanging or hooking a peripheral accessory. Moreover, the bracket 10 has two bended parts 15 on the bottom surface, wherein the bended parts 15 and the coupling hoes 16 are designed for supporting and positioning the computer case 20.

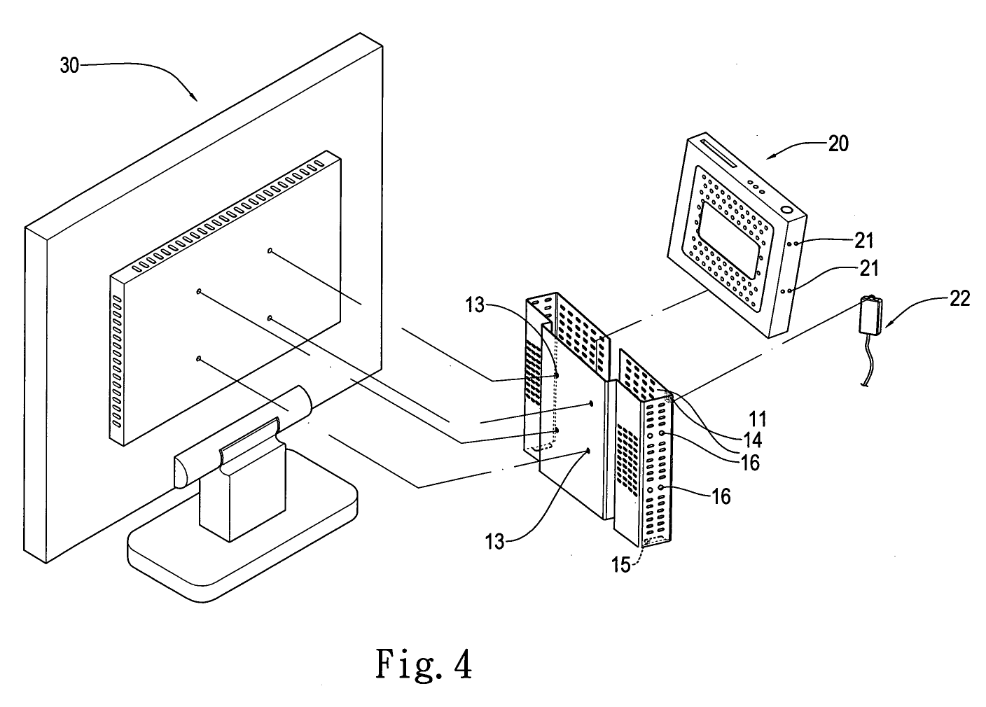

Referring to FIGS. 1 through 4, in practical use, the computer case 20 is inserted into the reception chamber 1 of the bracket 10. The computer case 20 has several coupling holes 21 formed thereon so that the computer case 20 can be fixedly screwed and positioned in the reception chamber 11 of the bracket 10 by the use of the coupling holes 21 of the computer case 20 and the coupling holes 16 of the bracket 10. In addition, after insertion into the reception chamber 11, the computer case 20 can be supported by the bended parts 15 of the bracket 10. In addition, the reception chamber 11 has a [symbol] shape, wherein a partial portion of the reception chamber 11 correspondingly defined by the protrudent part 12 of the bracket 10 is used for heat dissipation. In addition, the protrudent part 12 has several openings 13 to facilitate mounting and positioning of the computer case 20. Referring to FIG. 4, the hooking part 14 of the bracket 10 is designed for hanging thereon a transformer 22. The bracket 10 can be coupled with the backside of a LCD monitor 30 by the use of the openings 13 formed on the protrudent part 12 of the bracket 10 in such as manner that the bracket 10 does not occupy the space available on the user's desk and that the length of the power cord for connecting the computer case 20 with the LCD monitor 30 can be shortened so as to increase its practicability and convenience.

To sum up, the computer case fixing structure of the present invention indeed achieves the expected objects. Accordingly, the present invention satisfies all requirements for patentability and is therefore submitted for a patent.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. A computer case fixing structure, comprising:
a bended bracket for forming a reception chamber, said bracket having a protrudent part at the middle of one side thereof, said protrudent part having a plurality of openings, whereby a computer case can be inserted into said reception chamber of said bracket to facilitate hanging and positioning of said computer case by the use of said openings of said protrudent part.

2. A computer case fixing structure according to claim 1, wherein said bracket has a hooking part on one side for hanging a transformer of said computer case.

3. A computer case fixing structure according to claim 1, wherein said bracket has a bended part on the bottom for supporting said computer case after insertion of said computer case into said reception chamber.

4. A computer case fixing structure according to claim 1, wherein said bracket has a plurality of coupling holes on the lateral surface for coupling with said computer case after insertion of said computer case into said bracket.

5. A computer case fixing structure according to claim 1, wherein the other side of said bracket is bended to form two plates so as to facilitate insertion of said computer case into said expandable reception chamber of said bracket.

6. A computer case fixing structure according to claim 1, wherein said bracket has a [symbol] shape.

7. A computer case fixing structure according to claim 1, wherein said bracket has a plurality of heat dissipation holes.

8. A computer case fixing structure according to claim 1, wherein said openings on four corners of said protrudent part of said bracket are spaced 75 mm×75 mm to meet a VESA standard.

9. A computer case fixing structure according to claim 1, wherein said openings on four corners of said protrudent part of said bracket are spaced 100 mm×100 mm to meet a VESA standard.
